(19) United States
(12) Patent Application Publication
(10) Pub. No.: US 2016/0293879 A1
(43) Pub. Date: Oct. 6, 2016

(54) ORGANIC LIGHT EMITTING DIODE DEVICE AND DISPLAY DEVICE

(71) Applicants: BOE TECHNOLOGY GROUP CO., LTD., Beijing (CN); ORDOS YUANSHENG OPTOELECTRONICS CO., LTD, Ordos, Inner Mongolia (CN)

(72) Inventors: Lei CHEN, Beijing (CN); Haidong WU, Beijing (CN); Tae Gyu KIM, Beijing (CN)

(73) Assignee: BOE TECHNOLOGY GROUP CO., LTD., Beijing (CN)

(21) Appl. No.: 14/436,786

(22) PCT Filed: Oct. 30, 2014
(86) PCT No.: PCT/CN2014/089913

§ 371 Date: Apr. 17, 2015

(30) Foreign Application Priority Data
Aug. 20, 2014 (CN) 201410413349.8

(51) Int. Cl. H01L 51/50; H01L 51/56; H01L 51/52

(52) U.S. Cl. CPC H01L 51/5068; H01L 51/5084; H01L 51/5072; H01L 51/5234; H01L 51/56; H01L 51/5092

(57) ABSTRACT

An organic light emitting diode device and a display device are disclosed. The organic light emitting diode device includes a cathode (7), an anode (1) and an emitting layer (4) between the cathode (7) and the anode (1), further includes a first charge generation layer (10) and a second charge generation layer (11), and/or, a third charge generation layer (12) and a fourth charge generation layer (13). The first charge generation layer (10) and the second charge generation layer (11) are disposed between the cathode (7) and the emitting layer (4), the first charge generation layer (10) is close to the emitting layer (4) and configured for transporting electrons. The third charge generation layer (12) and the fourth charge generation layer (13) are disposed between the anode (1) and the emitting layer (4) and the fourth charge generation layer (13) is close to the emitting layer (4) for transporting holes. Since electrons and holes need not be generated by the cathode (7) or the anode (1), there is no limitation on materials for the cathode and the anode.

### TECHNICAL FIELD

Embodiments of the present invention relate to an organic light emitting diode device and a display device.

### BACKGROUND

OLED (organic light-emitting diode) devices have been widely used in illumination and display fields. As illustrated in FIG. 1, the basic configuration of an OLED device comprises: an anode 1, a cathode 7 and an organic layer 9, wherein the organic layer 9 may be further subdivided into a hole injection layer (HIL) 2, a hole transport layer (HTL) 3, an emitting layer (EML) 4, an electron transport layer (ETL) 5 and an electron injection layer (EIL) 6. In organic light emitting diode devices, light emission is implemented by irradiation of excitons formed by combining holes (h⁺) injected from the anode 1 and electrons (e⁻) injected from the cathode 7 in the emitting layer 4.

### SUMMARY

In an aspect, an embodiment of the present invention provides an organic light emitting diode device comprising a cathode, an anode and an emitting layer disposed between the cathode and the anode, further comprising a first charge generation layer and a second charge generation layer, and/or, a third charge generation layer and a fourth charge generation layer; wherein,

the first charge generation layer and the second charge generation layer are located between the cathode and the emitting layer, the first charge generation layer is close to the emitting layer and configured for transporting electrons; and the second charge generation layer is close to the cathode and configured for transporting holes; and

the third charge generation layer and the fourth charge generation layer are located between the anode and the emitting layer, the third charge generation layer is close to the anode and configured for transporting electrons; and the fourth charge generation layer is close to the emitting layer and configured for transporting holes.

In another aspect, an embodiment of the present invention provides a display device comprising the above-mentioned organic light emitting diode device.

### BRIEF DESCRIPTION OF THE DRAWINGS

In order to explain embodiments of the present invention or known technical solutions more clearly, accompanying drawings that need to be used in embodiments or known description will be briefly described below. Obviously, accompanying drawings described below are only some embodiments of the present invention rather than limiting the present invention.

FIG. 1 is a schematic diagram of a basic configuration of a known OLED device;

FIG. 2 is a schematic diagram of a basic configuration of a known OLED device with ITO as cathode;

FIG. 3 is a schematic diagram of a basic configuration of an OLED device provided in an embodiment of the present invention;

FIG. 4 is a schematic diagram of a basic configuration of an OLED device provided in an embodiment of the present invention;

FIG. 5 is a schematic diagram of a basic configuration of an OLED device provided in an embodiment of the present invention;

FIG. 6 is a schematic diagram of a basic configuration of an OLED device provided in an embodiment of the present invention;

FIG. 7 is a schematic diagram of a basic configuration of an OLED device provided in an embodiment of the present invention;

FIG. 8 is a schematic diagram of a basic configuration of an OLED device provided in an embodiment of the present invention;

FIG. 9 is a schematic diagram of a basic configuration of an OLED device provided in an embodiment of the present invention; and

FIG. 10 is a schematic diagram of a basic configuration of an OLED device provided in an embodiment of the present invention.

Reference numerals:

1—Anode; 2—Hole injection layer; 3—Hole transport layer; 4—Emitting layer; 5—Electron transport layer; 6—Electron injection layer; 7—Cathode; 8—Organic protection layer; 9—Organic layer; 10—First charge generation layer; 11—Second charge generation layer; 12—Third charge generation layer; 13—Fourth charge generation layer.

### DETAILED DESCRIPTION

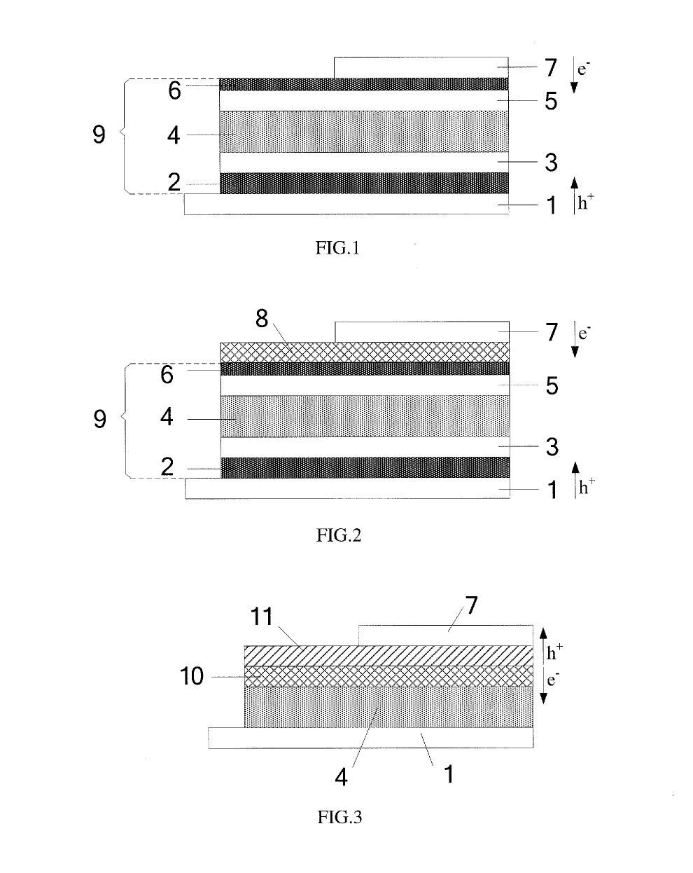

In a known organic light emitting diode device illustrated in FIG. 2, an organic protection layer 8, which may be formed of for example MoO₃ (molybdenum oxide), PEDOT (poly-ethylene dioxy-thiophene), or CuPc (phthalocyanine copper) etc., is inserted between the cathode 7 formed of ITO and the organic layer 9. Since the cathode 7 formed of ITO has a high work function and the presence of the organic protection layer 8, the following problems in two aspects have been brought about. In the first aspect, between the cathode 7 formed of ITO and the organic protection layer 8, the energy barrier difference between the organic protection layer 8 and the electron transport layer 6 is large, which might impede the injection and transmission of electrons, hence reducing working efficiency and lifetime of the device. In the second aspect, electrons from the cathode 7 made of ITO need to pass through the protection layer 8 so as to be injected into the emitting layer 4, which could reduce the injection and transmission efficiency of electrons.

Embodiments of the present invention provide an organic light emitting diode device and a display device that prevent electrons and holes to be injected into the emitting layer from being directly generated in cathode or anode, thus the limitation on the material of cathode or anode is eliminated, and further increase the device's working efficiency and service life.

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the embodiments of the present invention, those skilled in the art can obtain all other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at lease one. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

An embodiment of the present invention provides an organic light emitting diode device as illustrated in FIGS. 3-6, comprising a cathode 7, an anode 1 and an emitting layer 4 between the cathode 7 and the anode 1, and further comprising a first charge generation layer 10 and a second charge generation layer 11, and/or, a third charge generation layer 12 and a fourth charge generation layer 13; wherein,

The first charge generation layer 10 and the second charge generation layer 11 are located between the cathode 7 and the emitting layer 4, and the first charge generation layer 10 is close to the emitting layer 4 for transporting electrons e⁻; and the second charge generation layer 11 is close to the cathode 7 for transporting holes h⁺; and

The third charge generation layer 12 and the fourth charge generation layer 13 are located between the anode 1 and the emitting layer 4, and the third charge generation layer 12 is close to the anode 1 for transporting electrons e⁻; and the fourth charge generation layer 13 is close to the emitting layer 4 for transporting holes h⁺.

It is to be noted that both the first charge generation layer and the second charge generation layer are located between the cathode and the emitting layer, that is, both the first charge generation layer and the second charge generation layer are located between cathode and anode, then, when the cathode and the anode are applied with a voltage at the same time, under the action of the electric field, electrons and holes are generated at the interface between the first charge generation layer and the second charge generation layer and electrons are injected into the emitting layer through the first charge generation layer. That is, generation and injection of electrons injected into the emitting layer are independent of the cathode material, then the selection of cathode material is not limited by work function etc., and any electrically conducting material may be used for the cathode, thereby widening the selection range of cathode materials for the light emitting diode device.

Similarly, both the third charge generation layer and the fourth charge generation layer are located between the anode and the emitting layer, that is, both the third charge generation layer and the fourth charge generation layer are located between cathode and anode, then, when the cathode and the anode are applied with a voltage at the same time, under the action of the electric field, electrons and holes are generated at the interface between the third charge generation layer and the fourth charge generation layer and holes are injected into the emitting layer through the fourth charge generation layer. That is, generation and injection of holes injected into the emitting layer are independent of the anode material, then the selection of anode material is not limited by work function etc., and any electrically conducting material may be used for the anode, thereby widening the selection range of anode materials for the light emitting diode device.

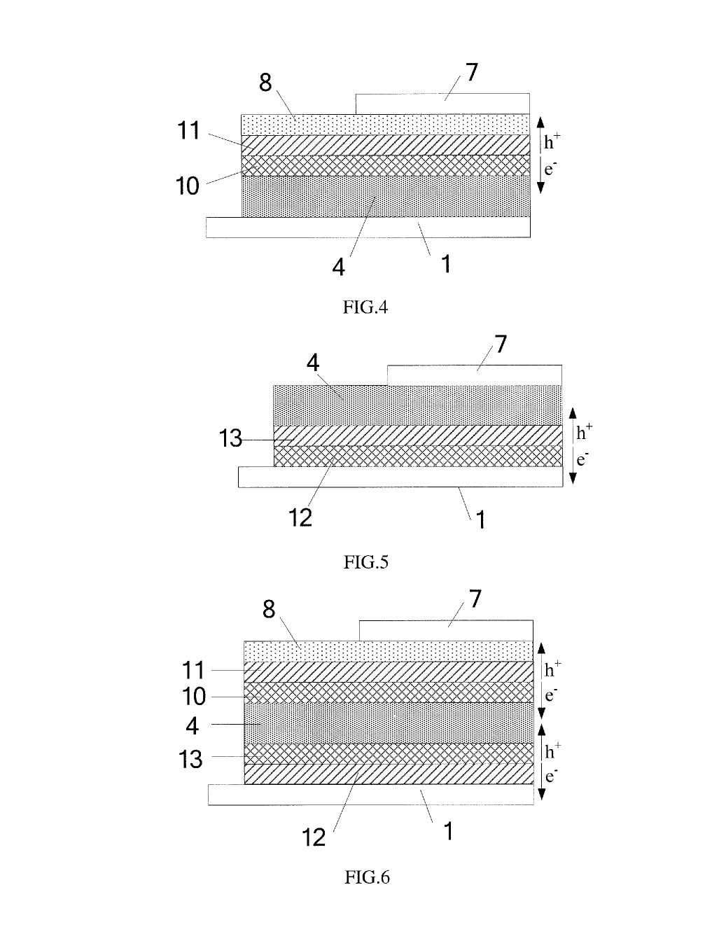

In the embodiment of the present invention, the organic light emitting diode device comprises a first charge generation layer and a second charge generation layer, and/or, a third charge generation layer and a fourth charge generation layer. That is, the organic light emitting diode device may merely comprise a first charge generation layer 10 and a second charge generation layer 11, as illustrated in FIGS. 3 and 4. Alternatively, the organic light emitting diode device may merely comprise a third charge generation layer 12 and a fourth charge generation layer 13, as illustrated in FIG. 5. Alternatively, the organic light emitting diode device may also comprise a first charge generation layer 10, a second charge generation layer 11, a third charge generation layer 12 and a fourth charge generation layer 13, as illustrated in FIG. 6.

For example, the first charge generation layer and the third charge generation layer may be organic n-type doped layers, the second charge generation layer and the fourth charge generation layer may be metal oxide layers, organic layers or organic p-type doped layers. In addition, the first charge generation layer, the second charge generation layer, the third charge generation layer and the fourth charge generation layer may also be non-doped layers. Each of the first charge generation layer, the second charge generation layer, the third charge generation layer and the fourth charge generation layer may have thicknesses of for example 5-20 nm.

The specific materials for the first charge generation layer and the second charge generation layer will be described in detail below with the first charge generation layer and the second charge generation layer as examples. For the third charge generation layer and the fourth charge generation layer, the first charge generation layer and the second charge generation layer may be referred to.

In one example, the first charge generation layer is an organic n-type doped layer, the second charge generation layer is a metal oxide layer. For example, the first charge generation layer may be an organic n-type doped layer formed of Alq3 (tri-(8-hydroxyquinoline) aluminum) and Mg (magnesium). Accordingly, the second charge generation layer may be a metal oxide layer formed of WO₃ (tungsten trioxide). Alternatively, the first charge generation layer may be an organic n-type doped layer formed of Bphen (4, 7-diphenyl-1, 10-phenanthrolene) and Li (lithium). Accordingly, the second charge generation layer may be a metal oxide layer formed of MoO₃ (molybdenum trioxide). Alternatively, the first charge generation layer may be an organic n-type doped layer formed of BCP (2, 9-dimethyl-4, 7-diphenyl-1, 10-phenanthroline) and Li (lithium). Accordingly, the second charge generation layer may be a metal oxide layer formed of V₂O₅ (vanadium pentoxide).

In another example, the first charge generation layer is an organic n-type doped layer, and the second charge generation layer is an organic layer. For example, the first charge generation layer may be an organic n-type doped layer formed of Alq3 (tri-(8-hydroxyquinoline) aluminum) and Li (lithium). Accordingly, the second charge generation layer may be an organic layer formed of HAT-CN (2,3,6,7,10,11-hexa-cyan-1,4,5,8,9,12-hexa-nitrilo-triphenylene).

In yet another example, the first charge generation layer is an organic n-type doped layer, and the second charge generation layer is an organic p-type doped layer. Alternatively, the first charge generation layer may be an organic n-type doped layer formed of Bphen (4, 7-diphenyl-1, 10-phenanthrolene) and Cs (cesium). Accordingly, the second charge generation layer may be an organic p-type doped layer formed of NPB (N, N′-diphenyl-N, N′-bis(1-naphthyl)-1,1′-diphenyl-4,4′-diamine) and F4-TCNQ (2,3,5,6-tetrafluorine-7,7′,8,8′-tetracyano-dimethyl para-quinone). Alternatively, the first charge generation layer may be an organic n-type doped layer formed of TPBI (1,3,5-tri-(1-phenyl-1H-benzimidazole-2-yl)benzene) and Li (lithium). Accordingly, the second charge generation layer may be an organic p-type doped layer formed of NPB (N, N′-diphenyl-N, N′-bis(1-naphthyl)-1,1′-diphenyl-4,4′-diamine) and FeCl₃ (iron trichloride). Alternatively, the first charge generation layer may be an organic n-type doped layer formed of Alq3 (tri-(8-hydroxyquinoline) aluminum) and Mg (magnesium). Accordingly, the second charge generation layer may be an organic p-type doped layer formed of m-MTDATA (4,4′,4″-tri-(N-3-methoxyphenyl-N-phenyl azyl) triphenylamine) and F4-TCNQ (2,3,5,6-tetrafluorine-7,7′,8,8′-tetracyano-dimethyl para-quinone).

In yet another example, the first charge generation layer and the second charge generation layer are both non-doped layers. For example, the first charge generation layer may be a non-doped layer formed of F16CuPc (perfluoro-phthalocyanine copper), and accordingly, the second charge generation layer may be a non-doped layer formed of CuPc (phthalocyanine copper).

The emitting layer may be formed of red, blue or green fluorescent or phosphorescent materials according to practical requirements with a thickness of for example 20-60 nm.

Of course, materials for the first charge generation layer, the second charge generation layer, the third charge generation layer, the fourth charge generation layer and the emitting layer are not limited to the above-mentioned materials which are only examples for describing embodiments of the present invention.

The organic light emitting diode devices provided in embodiments of the present invention will be described in detail below with reference to the accompanying drawings.

### Embodiment I:

As illustrated in FIG. 3, an organic light emitting diode device provided in an embodiment of the present invention comprises: an anode 1, an emitting layer 4, a cathode 7, a first charge generation layer 10 and a second charge generation layer 11. The emitting layer 4 is located between the anode 1 and the cathode 7, the first charge generation layer 10 and the second charge generation layer 11 are located between the cathode 7 and the emitting layer 4, and the first charge generation layer 10 is close to the emitting layer 4 for transporting electrons e⁻ to the emitting layer 4. In the organic light emitting diode device illustrated in FIG. 3, the anode 1 may be formed of ITO with high work function to facilitate transporting holes h⁺ to the emitting layer 4. Since electrons e⁻ are generated in both the first charge generation layer 10 and the second charge generation layer 11, and they are injected directly into the emitting layer 4 through the first charge generation layer 10, the cathode 7 may be of any electrically conducting material. For example, the cathode 7 may also be formed of ITO with high work function and good ductility. When the cathode 7 is formed of ITO with good ductility, as illustrated in FIG. 4, the cathode 7 is located over the second charge generation layer 11, and a protection layer 8 is formed between the cathode 7 and the second charge generation layer 11. For example, when the electrode layer is formed of ITO, it is typically formed by magnetron sputtering method and the cathode 7 is located over the second charge generation layer 11. In order to avoid damage to the second charge generation layer 11 by high temperature sputtering while forming the cathode 7 by magnetron sputtering, the protection layer 8 is formed on the second charge generation layer 11. Since ITO has good ductility, the organic light emitting diode device illustrated in FIG. 4 may be applicable to flexible display equipments. In the embodiments of the present invention and the accompanying drawings, when the first charge generation layer 10 and the second charge generation layer 11 are located between the cathode 7 and the emitting layer 4, the protection layer 8 is further formed between the cathode 7 and the second charge generation layer 11 with respect to a cathode 7 formed of ITO as an example.

### Embodiment II:

As illustrated in FIG. 5, an embodiment of the present invention further provides an organic light emitting diode device comprising: an anode 1, a cathode 7, an emitting layer 4, a third charge generation layer 12 and a fourth charge generation layer 13. The emitting layer 4 is located between the anode 1 and the cathode 7, the third charge generation layer 12 and the fourth charge generation layer 13 are located between the anode 1 and the emitting layer 4, and the fourth charge generation layer 13 is close to the emitting layer for transporting holes h⁺ to the emitting layer 4. In the organic light emitting diode device illustrated in FIG. 5, the cathode 7 may be formed of a metal with low work function and high conductivity to facilitate transporting electrons e⁻ to the emitting layer 4. Since holes h⁺ are generated in the third charge generation layer 12 and the fourth charge generation layer 13 and injected directly into the emitting layer 4, the anode 1 may be formed of any electrically conducting material, such as a metal material with higher conductivity.

Embodiment III:

As illustrated in FIG. 6, an embodiment of the present invention further provides an organic light emitting diode device comprising: an anode 1, a first charge generation layer 10, a second charge generation layer 11, an emitting layer 4, a third charge generation layer 12, a fourth charge generation layer 13 and a cathode 7.

The first charge generation layer 10 and the second charge generation layer 11 are located between the cathode 7 and the emitting layer 4, and the first charge generation layer 10 is close to the emitting layer 4 for transporting electrons e⁻ to the emitting layer 4. The third charge generation layer 12 and the fourth charge generation layer 13 are located between the anode 1 and the emitting layer 4, and the fourth charge generation layer 13 is close to the emitting layer 4 for transporting holes h⁺ to the emitting layer 4. In the organic light emitting diode device illustrated in FIG. 6, both the cathode and the anode may be formed of metals with high conductivity. Alternatively, both the cathode and the anode may be formed of ITO with good ductility to allow the organic light emitting diode device to be applicable to flexible display equipments.

### Embodiment IV:

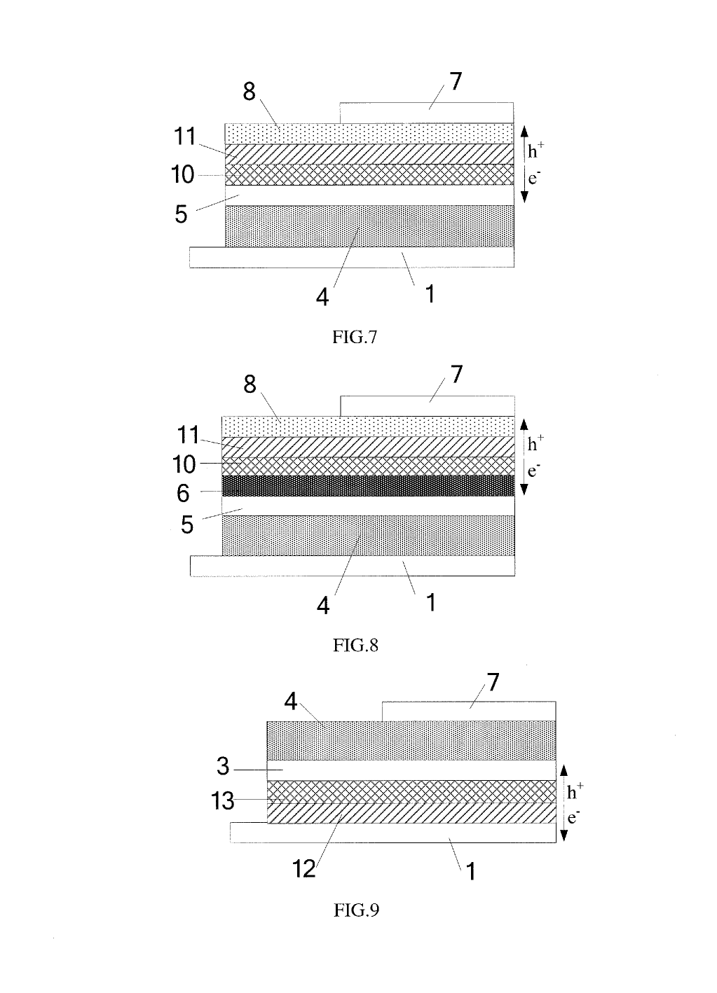

As illustrated in FIG. 7, an embodiment of the present invention further provides an organic light emitting diode device comprising: an anode 1 a cathode 7, an emitting layer 4, a first charge generation layer 10, a second charge generation layer 11 and an electron transport layer 5. The electron transport layer 5 is located between the first charge generation layer 10 and the emitting layer 4. Then, when the first charge generation layer 10 and the second charge generation layer 11 generate electrons e⁻ and holes h⁺ under the action of electric field, electrons e⁻ are injected into the emitting layer 4 through the first charge generation layer 10 and the electron transport layer 5. The electron transport layer 5 facilitates transportation of electrons e⁻, can in turn increase the transportation efficiency of electrons e⁻ injected into the emitting layer 4 and enhance the performance of the organic light emitting diode device.

For example, the electron transport layer may be formed of Bphen (4, 7-diphenyl-1, 10-phenanthrolene) or TmPyPB (1,3,5-tri-[(3-pyridyl)-3-phenyl] benzene) with a thickness of 10-30 nm.

It is to be noted that the organic light emitting diode device illustrated in FIG. 7 may further comprise a third charge generation layer and a fourth charge generation layer both of which are located between the anode 1 and the emitting layer 4.

### Embodiment V:

As illustrated in FIG. 8, an embodiment of the present invention further provides an organic light emitting diode device comprising: an anode 1, a cathode 7, an emitting layer 4, a first charge generation layer 10, a second charge generation layer 11, an electron transport layer 5 and an electron injection layer 6, wherein the electron injection layer 6 is located between the first charge generation layer 10 and the electron transport layer 5. Then, when the first charge generation layer 10 and the second charge generation layer 11 generate electrons e⁻ and holes h⁺ under the action of electric field, electrons e⁻ are injected into the emitting layer 4 through the first charge generation layer 10 and the electron transport layer 5 as well as the electron injection layer 6. The electron injection layer 6 facilitates injection of electrons in turn can increase the injection efficiency of electrons injected into the emitting layer 4 and enhance the performance of the organic light emitting diode device.

It is to be noted that the organic light emitting diode device illustrated in FIG. 8 may further comprise a third charge generation layer and a fourth charge generation layer both of which are located between the anode 1 and the emitting layer 4.

### Embodiment VI:

As illustrated in FIG. 9, an embodiment of the present invention further provides an organic light emitting diode device comprising an anode 1, a cathode 7, an emitting layer 4, a third charge generation layer 12, a fourth charge generation layer 13 and a hole transport layer 3, wherein the hole transport layer 3 is located between the fourth charge generation layer 13 and the emitting layer 4. Then, when the third charge generation layer 12 and the fourth charge generation layer 13 generate electrons e⁻ and holes h⁺ under the action of electric field, holes h⁺ are injected into the emitting layer 4 through the fourth charge generation layer 13 and the hole transport layer 3. The hole transport layer 3 facilitates transportation of holes h⁺, in turn can increase the transportation efficiency of holes h⁺ injected into the emitting layer 4 and enhance the performance of the organic light emitting diode device.

The hole transport layer may be formed of organic material NPB (N, N′-diphenyl-N, N′-bis-(1-naphthyl)-1,1′-diphenyl-4,4′-diamine) or CBP (4,4′-N, N′-bi-carbazole diphenyl) with a thickness of 20-70 nm.

It is to be noted that the organic light emitting diode device illustrated in FIG. 9 may further comprise a first charge generation layer and a second charge generation layer between the cathode 7 and the emitting layer 4. Alternatively, a first charge generation layer, a second charge generation layer and an electron transport layer are disposed between the cathode 7 and the emitting layer 4. Alternatively, a first charge generation layer, a second charge generation layer, an electron transport layer and an electron injection layer are disposed between the cathode 7 and the emitting layer 4.

### Embodiment VII:

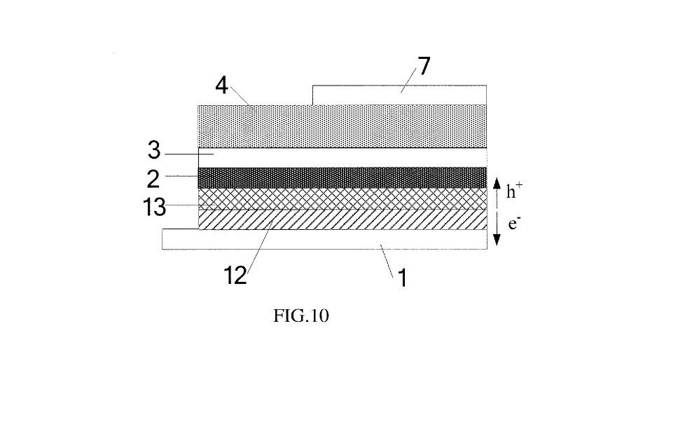

As illustrated in FIG. 10, an embodiment of the present invention further provides an organic light emitting diode device comprising: an anode 1, a cathode 7, an emitting layer 4, a third charge generation layer 12, a fourth charge generation layer 13, a hole transport layer 3 and a hole injection layer 2, wherein the hole injection layer 2 is located between the fourth charge generation layer 13 and the hole transport layer 3. Then, when the third charge generation layer 12 and the fourth charge generation layer 13 generate electrons e⁻ and holes h⁺ under the action of electric field, holes h⁺ are injected into the emitting layer 4 through the fourth charge generation layer 13, the hole transport layer 3 and the hole injection layer 2. The hole injection layer 2 facilitates injection of holes h⁺, in turn can increase the injection efficiency of holes h⁺ injected into the emitting layer 4 and enhance the performance of the organic light emitting diode device.

The hole injection layer may be formed of metal oxides such as MoO₃ (molybdenum trioxide); may be a p-type doped layer, such as an organic p-type doped layer formed of NPB (N, N′-diphenyl-N, N′-bis-(1-naphthyl)-1,1′-diphenyl-4,4′-diamine) and MoO₃ (molybdenum trioxide), or an organic p-type doped layer formed of NPB (N, N′-diphenyl-N, N′-bis-(1-naphthyl)-1,1′-diphenyl-4,4′-diamine) and FeCl₃ (iron trichloride), or an organic p-type doped layer formed of CBP (4,4′-N,N′-bi-carbazole diphenyl) and WO₃ (tungsten trioxide), or an organic p-type doped layer formed of m-MTDATA (4,4′,4″-tri-(N-3-methoxyphenyl-N-phenyl azyl)triphenylamine)) and F4TCNQ (2,3,5,6-tetra-fluoro-7,7′,8,8′-tetracyano dimethyl para-benzoquinone). The thickness of the hole injection layer is 1-30 nm.

It is to be noted that the organic light emitting diode device illustrated in FIG. 10 may further comprise a first charge generation layer and a second charge generation layer disposed between the cathode 7 and the emitting layer 4. Alternatively, a first charge generation layer, a second charge generation layer and an electron transport layer are disposed between the cathode 7 and the emitting layer 4. Alternatively, a first charge generation layer, a second charge generation layer, an electron transport layer and an electron injection layer are disposed between the cathode 7 and the emitting layer 4.

An embodiment of the present invention further provides a display device comprising the organic light emitting diode device provided in any one of embodiments of the present invention. The display device may be a display device, such as an OLED (organic light emitting diode) display and any product or component with display function comprising these display devices, such as a TV set, a digital camera, a mobile phone and a tablet computer.

In one example, the organic light emitting diode device comprises at least a first charge generation layer and a second charge generation layer. Therefore, the cathode and the anode of the organic light emitting diode device may both be formed of ITO and the display device may be a flexible display device. For example, the organic light emitting diode device may be as illustrated in FIG. 4, 6, 7, or 8. The embodiment of the present invention may be for example a display device comprising the organic light emitting diode device of FIG. 8.

Since the ITO has ductility, organic light emitting diode devices with cathodes and anodes formed of ITO may be applied in flexible display devices, which prevents the cathodes from breaking when cathodes in flexible display devices are formed of metals. Further, in the organic light emitting diode device, electrons are generated by the first charge generation layer and the second charge generation layer and directly injected into the emitting layer through the first charge generation layer. The organic light emitting diode device provided in embodiments of the present invention increases the injection efficiency of electrons and facilitates enhancing performance of the organic light emitting diode device as compare to the known electron injection mode in which cathode is of ITO and electrons have to pass through the protection layer to be injected into the emitting layer.

In the organic light emitting diode device and the display device provided in the above-mentioned embodiments of the present invention, the organic light emitting diode device comprises a cathode, an anode and an emitting layer between the cathode and the anode, and further comprises a first charge generation layer and a second charge generation layer, and/or, a third charge generation layer and a fourth charge generation layer. When the cathode and the anode are applied with a voltage at the same time, under the action of the electric field, electrons and holes are generated at the interface between the first charge generation layer and the second charge generation layer, and electrons are injected into the emitting layer through the first charge generation layer. Compared to generating electrons and injecting electrons into the emitting layer directly by the cathode as already known, in the organic light emitting diode device provided in embodiments of the present invention, the cathode may be formed of any electrically conducting material, particularly ITO with high work function and good ductility, the organic light emitting diode device may be applied to flexible display. And electrons are injected into the emitting layer directly through the first charge generation layer, which increases the injection efficiency of electrons, facilitates enhancing performance of the organic light emitting diode device and extends the lifetime of the organic light emitting diode device as compared to injecting electrons into the emitting layer through the protection layer. When the cathode and the anode are applied with a voltage at the same time, under the action of the electric field, electrons and holes are generated at the interface between the third charge generation layer and the fourth charge generation layer and the holes are injected into the emitting layer through the fourth charge generation layer, which eliminates the limitation on the anode material due to that the holes injected into the emitting layer will not generated in the anode.

What is described above is related to the illustrative embodiments of the disclosure only and not limitative to the scope of the disclosure; the scopes of the disclosure are defined by the accompanying claims.

The present application claims priority of China Patent application No. 201410413349.8 filed on Aug. 20, 2014, which is incorporated in its entirety by reference herein.

1. An organic light emitting diode device comprising a cathode, an anode and an emitting layer disposed between the cathode and the anode, further comprising a first charge generation layer and a second charge generation layer and/or a third charge generation layer and a fourth charge generation layer; wherein,
the first charge generation layer and the second charge generation layer are disposed between the cathode and the emitting layer, the first charge generation layer is close to the emitting layer and configured for transporting electrons; and the second charge generation layer is close to the cathode and configured for transporting holes; and
the third charge generation layer and the fourth charge generation layer are disposed between the anode and the emitting layer, the third charge generation layer is close to the anode and configured for transporting electrons; and the fourth charge generation layer is close to the emitting layer and configured for transporting holes.

2. The organic light emitting diode device of claim 1, wherein the organic light emitting diode device comprises the first charge generation layer and the second charge generation layer, and further comprises an electron transport layer; wherein the electron transport layer is disposed between the first charge generation layer and the emitting layer.

3. The organic light emitting diode device of claim 2, wherein the organic light emitting diode device further comprises an electron injection layer disposed between the first charge generation layer and the electron transport layer.

4. The organic light emitting diode device of claim 1, wherein the organic light emitting diode device comprises the third charge generation layer and the fourth charge generation layer, and further comprises a hole transport layer, wherein the hole transport layer is disposed between the fourth charge generation layer and the emitting layer.

5. The organic light emitting diode device of claim 4, wherein the organic light emitting diode device further comprises a hole injection layer disposed between the fourth charge generation layer and the hole transport layer.

6. The organic light emitting diode device of claim 2, wherein a material of the cathode has ductility.

7. The organic light emitting diode device of claim 6, wherein the material of the cathode is ITO.

8. The organic light emitting diode device of claim 7, wherein the cathode is disposed over the second charge generation layer and formed by magnetron sputtering method, and a protection layer is formed between the cathode and the second charge generation layer.

9. The organic light emitting diode device of claim 1, wherein the first charge generation layer and the third charge generation layer are organic n-type doped layers, the second charge generation layer and the fourth charge generation layer are metal oxide layers, organic layers or organic p-type doped layers; or the first charge generation layer, the second charge generation layer, the third charge generation layer and the fourth charge generation layer are all non-doped layers.

10. A display device comprising the organic light emitting diode device of claim 1.

11. The display device of claim 10, wherein the organic light emitting diode device comprises the first charge generation layer and the second charge generation layer, and further comprises an electron transport layer; wherein the electron transport layer is disposed between the first charge generation layer and the emitting layer.

12. The display device of claim 11, wherein the organic light emitting diode device further comprises an electron injection layer disposed between the first charge generation layer and the electron transport layer.

13. The display device of claim 10, wherein the organic light emitting diode device comprises the third charge generation layer and the fourth charge generation layer, and further comprises a hole transport layer, wherein the hole transport layer is disposed between the fourth charge generation layer and the emitting layer.

14. The display device of claim 13, wherein the organic light emitting diode device further comprises a hole injection layer disposed between the fourth charge generation layer and the hole transport layer.

15. The display device of claim 11, wherein a material of the cathode has ductility.

16. The display device of claim 15, wherein the material of the cathode is ITO.

17. The display device of claim 16, wherein the cathode is disposed over the second charge generation layer and formed by magnetron sputtering method, and a protection layer is formed between the cathode and the second charge generation layer.

18. The display device of claim 10, wherein the first charge generation layer and the third charge generation layer are organic n-type doped layers, the second charge generation layer and the fourth charge generation layer are metal oxide layers, organic layers or organic p-type doped layers; or the first charge generation layer, the second charge generation layer, the third charge generation layer and the fourth charge generation layer are all non-doped layer.
